(19) United States
(12) Patent Application Publication
(10) Pub. No.: US 2010/0178758 A1
(43) Pub. Date: Jul. 15, 2010

(54) METHODS FOR FABRICATING DIELECTRIC LAYER AND NON-VOLATILE MEMORY

(75) Inventors: Jeng-Hwa Liao, Hsinchu (TW); Jung-Yu Hsieh, Hsinchu (TW); Ling-Wu Yang, Hsinchu (TW)

Correspondence Address: J C PATENTS, 4 VENTURE, SUITE 250, IRVINE, CA, 92618, US

(73) Assignee: MACRONIX INTERNATIONAL CO., LTD., Hsinchu (TW)

(21) Appl. No.: 12/354,602

(22) Filed: Jan. 15, 2009

(51) Int. Cl. H01L 21/443; H01L 21/28

(52) U.S. Cl. 438/591; 438/786; 257/E21.478; 257/E21.21

(57) ABSTRACT

The method for fabricating the dielectric layer of the present invention is described as follows. A substrate is provided in a chamber, wherein the chamber is a single-wafer LPCVD chamber. A silicon source gas, an oxidation source gas and a nitridation source gas are then introduced into the chamber, wherein a volumetric flow rate ratio of the oxidation source gas to a total amount of the oxidation source gas and the nitridation source gas is varied within a range of 0.0245 to 0.375. Afterwards, the dielectric layer with a dielectric constant within a range of 4.8 to 7.6 is formed on the substrate.

### BACKGROUND OF THE INVENTION

1. Field of the Invention

The present invention relates to a semiconductor process, and in particular, to a method for fabricating a silicon oxynitride layer using single-wafer low-pressure chemical vapor deposition (LPCVD) and to a method for fabricating a non-volatile memory.

2. Description of Related Art

Along with rapid progress of semiconductor technology, further advances in operating speed and performance of integrated circuits are demanded. In general, semiconductor devices benefit greatly from dielectric thin film construction. Silicon oxynitride is one of the dielectric films used in fabrication of the integrated circuits, and has properties between silicon oxide and silicon nitride.

Conventional processes for depositing silicon oxynitride films are usually carried out in a furnace. The furnace is a batch type system which processes multiple semiconductor wafers at a time. However, forming silicon oxynitride films by using batch type system usually takes several hours in a single process in order to conduct the reaction uniformly on each of the wafers. The conventional fabrication of silicon oxynitride films suffers from thermal budget issues due to the relatively long thermal cycles of the furnace. Therefore, qualities of silicon oxynitride films formed by the above-mentioned method are subjected to a serious impact.

As a result, how to effectively fabricate silicon oxynitride layer with desired properties and also reduce the thermal budget for ensuring the process reliability and the performance of subsequently-formed devices is one of the immediate issues to be solved in the art.

### SUMMARY OF THE INVENTION

Accordingly, the present invention is directed to a method for fabricating a dielectric layer using single-wafer LPCVD.

The present invention is directed to a method for fabricating a dielectric layer with a low thermal budget.

The present invention is also directed to a method for fabricating a non-volatile memory including a silicon oxynitride layer for trapping charges.

The method for fabricating the dielectric layer of the present invention is described as follows. A substrate is provided in a chamber, wherein the chamber is a single-wafer LPCVD chamber. A silicon source gas, an oxidation source gas and a nitridation source gas are then introduced into the chamber, wherein a volumetric flow rate ratio of the oxidation source gas to a total amount of the oxidation source gas and the nitridation source gas is varied within a range of 0.0245 to 0.375. Afterwards, the dielectric layer with a dielectric constant within a range of 4.8 to 7.6 is formed on the substrate.

According to an embodiment of the present invention, the oxidation source gas includes nitrous oxide (N₂O), the nitridation source gas includes ammonia (NH₃), and the silicon source gas includes silane (SiH₄), for example.

According to an embodiment of the present invention, a process pressure of the method is within a range of 50 Torr to 200 Torr.

According to an embodiment of the present invention, a process temperature of the method is within a range of 700° C. to 900° C.

According to an embodiment of the present invention, a refractive index of the dielectric layer is greater than or equal to 1.49 but less than 1.96 at a wavelength of 633 nm.

According to an embodiment of the present invention, a film stress of the dielectric layer ranges between 1.5×10⁸ dynes/cm² and 1.35×10¹⁰ dynes/cm².

According to an embodiment of the present invention, a duration of forming the dielectric layer on the substrate is within a range of 5 seconds to 3600 seconds.

The method for fabricating the dielectric layer of the present invention is described as follows. A substrate is provided in a deposition chamber. A process pressure is set within a range of 50 Torr to 200 Torr. A reactant gas including silane (SiH₄), nitrous oxide (N₂O) and ammonia (NH₃) are introduced into the deposition chamber, wherein a volumetric flow rate of SiH₄ is constant while a volumetric flow rate ratio of N₂O to (N₂O+NH₃) is varied within a range of 0.0245 to 0.375. A silicon oxynitride layer is then formed on the substrate.

According to an embodiment of the present invention, a volumetric flow rate ratio of SiH₄ to (N₂O+NH₃) is within a range of 1:2000 to 6:2000.

According to an embodiment of the present invention, a process temperature of the method is within a range of 700° C. to 900° C.

According to an embodiment of the present invention, a dielectric constant of the silicon oxynitride layer ranges between 4.8 and 7.6.

According to an embodiment of the present invention, a refractive index of the silicon oxynitride layer is greater than or equal to 1.49 but less than 1.96 at a wavelength of 633 nm.

According to an embodiment of the present invention, a film stress of the silicon oxynitride layer ranges between 1.5×10⁸ dynes/cm² and 1.35×10¹⁰ dynes/cm².

According to an embodiment of the present invention, the deposition chamber is a single-wafer low-pressure chemical vapor deposition (LPCVD) chamber.

According to an embodiment of the present invention, a duration of forming the silicon oxynitride layer on the substrate is within a range of 5 seconds to 3600 seconds.

The method for fabricating the non-volatile memory of the present invention is described as follows. A substrate is provided, and a tunnel layer is then formed on the substrate. A charge-trapping layer is formed on the tunnel layer using silane (SiH₄), nitrous oxide (N₂O) and ammonia (NH₃) as a reactant gas, wherein the charge-trapping layer has a refractive index greater than or equal to 1.49 but less than 1.96 at a wavelength of 633 nm. A top layer is formed on the charge-trapping layer. A gate is formed on the top layer.

According to an embodiment of the present invention, the method for fabricating the non-volatile memory further includes patterning the gate, the top layer, the charge-trapping layer and the tunnel layer, and forming a doped region in the substrate at both sides of the patterned tunnel layer.

According to an embodiment of the present invention, a volume flow rate of SiH₄ for forming the charge-trapping layer is a constant, and a volume flow rate of N₂O to (N₂O+NH₃) for forming the charge-trapping layer is varied within a range of 0.0245 to 0.375.

According to an embodiment of the present invention, a volumetric flow rate ratio of SiH₄ to (N₂O+NH₃) for forming the charge-trapping layer is within a range of 1:2000 to 6:2000.

According to an embodiment of the present invention, a method for forming the charge-trapping layer comprises a single-wafer LPCVD process.

According to an embodiment of the present invention, a process pressure of forming the charge-trapping layer is within a range of 50 Torr to 200 Torr.

According to an embodiment of the present invention, a process temperature of forming the charge-trapping layer is within a range of 700° C. to 900° C.

According to an embodiment of the present invention, wherein a thickness of the charge-trapping layer is about 30-100 Å.

According to an embodiment of the present invention, forming the tunnel layer includes forming a first oxide layer on the substrate, forming an oxynitride layer on the first oxide layer using silane (SiH₄), nitrous oxide (N₂O) and ammonia (NH₃) as a reactant gas, and forming a second oxide layer on the oxynitride layer. The oxynitride layer has a refractive index below 1.63 at a wavelength of 633 nm.

According to an embodiment of the present invention, a volume flow rate of SiH₄ for forming the oxynitride layer is a constant, and a volume flow rate of N₂O to (N₂O+NH₃) for forming the oxynitride layer is varied within a range of 0.0245 to 0.375.

According to an embodiment of the present invention, a volumetric flow rate ratio of SiH₄ to (N₂O+NH₃) for forming the oxynitride layer is within a range of 1:2000 to 6:2000.

According to an embodiment of the present invention, a method for forming the oxynitride layer comprises a single-wafer LPCVD process.

According to an embodiment of the present invention, a process pressure of forming the oxynitride layer is within a range of 50 Torr to 200 Torr.

According to an embodiment of the present invention, a process temperature of forming the oxynitride layer is within a range of 700° C. to 900° C.

According to an embodiment of the present invention, a thickness of the oxynitride layer is about 30-100 Å.

In summary, the method for fabricating the dielectric layer of the present invention is carried out by single-wafer LPCVD, and thereby the process time and thermal budget can be reduced.

In addition, the method for fabricating the non-volatile memory of the present invention forms the charge-trapping layer by means of the foregoing method of fabricating the dielectric layer. Accordingly, the fabrication of the non-volatile memory is simplified, and the properties of the charge-trapping layer can be adjusted on demand easily.

In order to make the aforementioned and other features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart of a method for fabrication a dielectric layer according a first embodiment of the present invention.

FIG. 2A illustrates an effect of varied volumetric flow rate ratios on the optical properties of the dielectric layer formed according to an example of the present invention.

FIG. 2B illustrates an effect of varied process pressure on the optical properties of the dielectric layer formed according to an example of the present invention.

FIG. 3 illustrates a distribution curve of the electrical properties versus the optical properties of the dielectric layer formed according to an example of the present invention.

FIG. 4 illustrates a distribution curve of the physical characteristics versus the optical properties of the dielectric layer formed according to an example of the present invention.

FIGS. 5A-5B are schematic cross-sectional views illustrating the fabrication process of a non-volatile memory according to a second embodiment of the present invention.

FIGS. 6A-6B are schematic cross-sectional views illustrating the fabrication process of a non-volatile memory according to a third embodiment of the present invention.

FIGS. 7A-7C respectively illustrate an effect of varied program time on electron density (Q) of the charge-trapping layer formed according to three examples of the present invention with different refractive indexes.

FIG. 8 illustrates distribution curves of flat band voltage (V_{FB}) versus varied program time of the non-volatile memory according to several examples of the present invention with different refractive indexes of the charge-trapping layer.

FIG. 9 illustrates distribution curves of flat band voltage (V_{FB}) versus varied program voltage (V_{PGM}) of the non-volatile memory according to several examples of the present invention with different refractive indexes of the charge-trapping layer.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the present invention, the fabrication of the dielectric layer involves introducing a silicon source gas, an oxidation source gas and a nitridation source gas as a reactant gas into a deposition chamber in which a substrate has been placed. The fabrication is carried out by using single-wafer LPCVD under a process pressure ranging from about 50 Torr to about 200 Torr and a process temperature ranging from about 700° C. to about 900° C. The silicon source gas, for example, includes silane (SiH₄). The oxidation source gas, for example, includes nitrous oxide (N₂O). The nitridation source gas, for example, includes ammonia (NH₃).

The properties of the dielectric layer to be formed on the substrate can be adjusted by varying the volumetric flow rate ratio of each component in the reactant gas. The volumetric flow rate ratio of the oxidation source gas to a total amount of the oxidation source gas and the nitridation source gas can be varied within a range of 0.0245 to 0.375, so as to obtain the dielectric layer with desired properties. In an embodiment, the dielectric layer formed under the foregoing conditions has a dielectric constant within a range of 4.8 to 7.6. In another embodiment, the dielectric layer formed under the foregoing conditions has a refractive index greater than or equal to 1.49 but less than 1.96 at a wavelength of 633 nm. In still another embodiment, the dielectric layer formed under the foregoing conditions has a film stress within a range of 1.5×10⁸ dynes/cm² to 1.35×10¹⁰ dynes/cm².

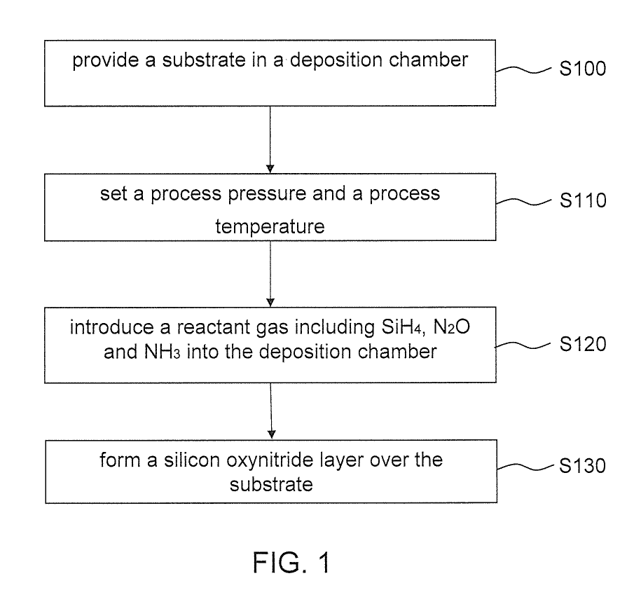

The implementation of the present invention is further described in a manner of a flow chart hereinafter. FIG. 1 is a flow chart of a method for fabrication a dielectric layer according a first embodiment of the present invention. In the following embodiments, the procedures for fabricating silicon oxynitride film are described to illustrate the present invention. It is to be understood that the following procedures are intended to explain the sequence of the steps of the method for fabricating the dielectric layer in the practical semiconductor process and thereby enable those of ordinary skill in the art to practice this invention, but are not intended to limit the scope of this invention.

Referring to FIG. 1, in step S100, a substrate is provided, which is placed in a deposition chamber. The substrate can be a semiconductor wafer, e.g. an N— or P-type silicon wafer, whereon thin films, conductive parts, or devices may be formed. In an embodiment, the substrate is placed in a single-wafer LPCVD chamber.

In next step S110, a process pressure and a process temperature are set, so as to obtain an appropriate process condition. In an embodiment, forming silicon oxynitride film in the subsequent procedure is performed at the process pressure within the range of 50 Torr to 200 Torr. In an embodiment, forming silicon oxynitride film in the subsequent procedure is performed at the process temperature within the range of 700° C. to 900° C., possibly 800° C.

Afterwards, in step S120, a reactant gas is introduced into the chamber, wherein the reactant gas may include SiH₄, N₂O and NH₃. In an embodiment, an inert gas, such as argon (Ar) or helium (He), may also be introduced into the chamber as a diluting gas or a carrier gas during the step S120. The volumetric flow rate ratio of N₂O to a total amount of N₂O and NH₃, that is, (N₂O+NH₃), is within the range of 0.0245 to 0.375, while the volumetric flow rate of SiH₄ is constant. In an embodiment, the volumetric flow rate ratio of SiH₄ to (N₂O+NH₃) is within a range of 1:2000 to 6:2000, possibly 4:2000.

It is noted that the volumetric flow rate ratio of the reactant gas depends on the silicon oxynitride film to be formed with various properties. In an example, SiH₄ is introduced into the chamber at a flow rate of about 4 sccm, N₂O is introduced into the chamber at a flow rate of about 49-750 sccm, and NH₃ is introduced into the chamber at a flow rate of about 1250-1951 sccm. Since N₂O can react with SiH₄ to form oxide prior to the nitridation reaction caused by NH₃ and SiH₄, the total amount of N₂O fed into the chamber is small.

After the step S120, the substrate is exposed to volatile precursors, that is, the reactant gas, which can decompose and react on the substrate to produce the deposition, such that a silicon oxynitride layer is formed on the substrate (step S130). The silicon oxynitride layer may be represented by the formula SiON or SiOₓN_{y} (x>0, y>0). The silicon oxynitride layer is, for example, formed on the substrate at a deposition rate within a range of 72 Å/minute to 240 Å/minute. The duration of the formation of the silicon oxynitride layer may be usually within the range of 5 seconds to 3600 seconds, depending on the desired thickness of the silicon oxynitride layer.

In an embodiment, the silicon oxynitride layer formed on the substrate is characterized by having a dielectric constant within a range of 4.8 to 7.6, depending on the various volumetric flow rate ratio of the reactant gas and the process pressure maintained in the deposition chamber. In another embodiment, the silicon oxynitride layer formed on the substrate is characterized by having a refractive index greater than or equal to 1.49 but less than 1.96 at a wavelength of 633 nm, depending on the various volumetric flow rate ratio of the reactant gas and the process pressure maintained in the deposition chamber. In still another embodiment, the silicon oxynitride layer formed on the substrate is characterized by having a film stress within a range of 1.5×10⁸ dynes/cm² to 1.35×10¹⁰ dynes/cm², depending on the various volumetric flow rate ratio of the reactant gas and the process pressure maintained in the deposition chamber.

It is noted that the method for fabricating the dielectric layer according to the first embodiment of the present invention is carried out by using single-wafer LPCVD, and thereby the process time can be much more reduced. That is to say, the duration of each substrate subjected to the high temperature is of the order of minutes, such that the thermal budget of the process can be diminished effectively.

To substantiate the properties of the dielectric layer formed according to the method of the present invention, the actual measurement and analysis of the dielectric formed according to several examples of the present invention will be described. It should be appreciated that this invention should not be construed as limited to the examples set forth herein.

### EXAMPLES I

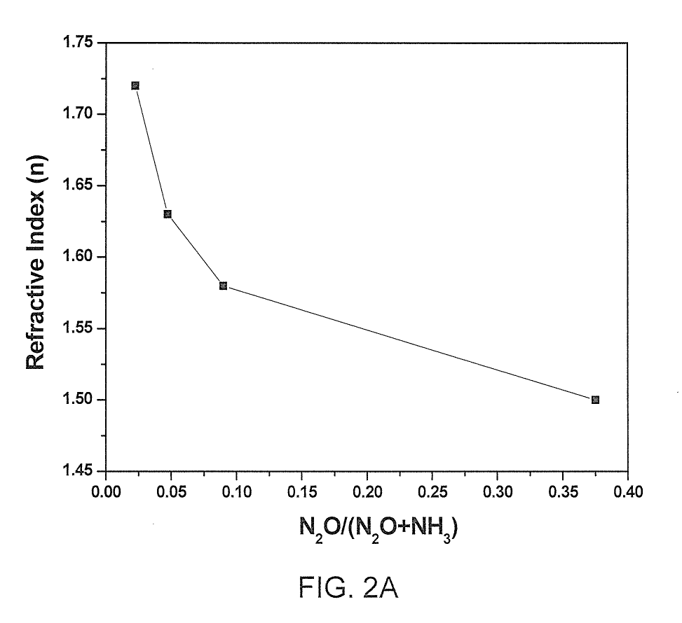

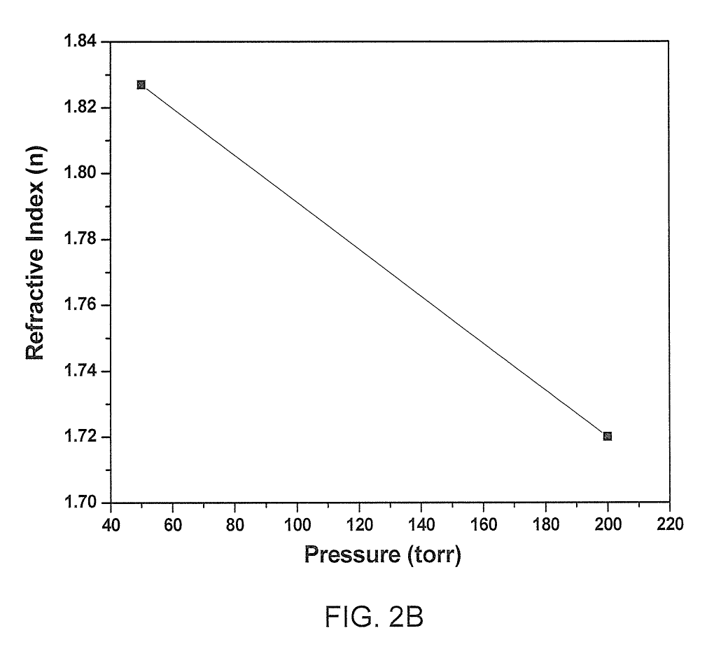

FIG. 2A illustrates an effect of varied volumetric flow rate ratios on the optical properties of the dielectric layer formed according to an example of the present invention.

In the experiments shown in FIG. 2A, the volumetric flow rate ratio of N₂O to (N₂O+NH₃) is varied to adjust the optical properties of the dielectric layer. In an example, the dielectric layer is formed at the process pressure of 200 Torr and at the process temperature of 800° C., and SiH₄ is fed into the chamber at the flow rate of 4 sccm. As illustrated by the curve shown in FIG. 2A, as the volumetric flow rate ratio of N₂O to (N₂O+NH₃) increases, the refractive index of the dielectric layer measured at a wavelength of 633 nm decreases. More specifically, the volumetric flow rate ratio of N₂O to (N₂O+NH₃) increasing from 0.0245 to 0.375 gives the refractive index decreasing from 1.73 to 1.49. Accordingly, the decrease in the refractive index is controlled by increasing the oxidation gas flow, that is, N₂O flow.

FIG. 2B illustrates an effect of varied process pressure on the optical properties of the dielectric layer formed according to an example of the present invention.

In the experiments shown in FIG. 2B, the process pressure is varied to adjust the optical properties of the dielectric layer. In an example, SiH₄, N₂O and NH₃ are fed into the chamber at the flow rate of 4 sccm, 49 sccm and 1951 sccm, respectively, under the process temperature of 800° C. As illustrated by the curve shown in FIG. 2B, as the process pressure increases from 50 Torr to 200 Torr, the refractive index of the dielectric layer decreases from 1.83 to 1.73 at a wavelength of 633 nm. Therefore, the decrease in the refractive index is controlled by increasing the deposition pressure.

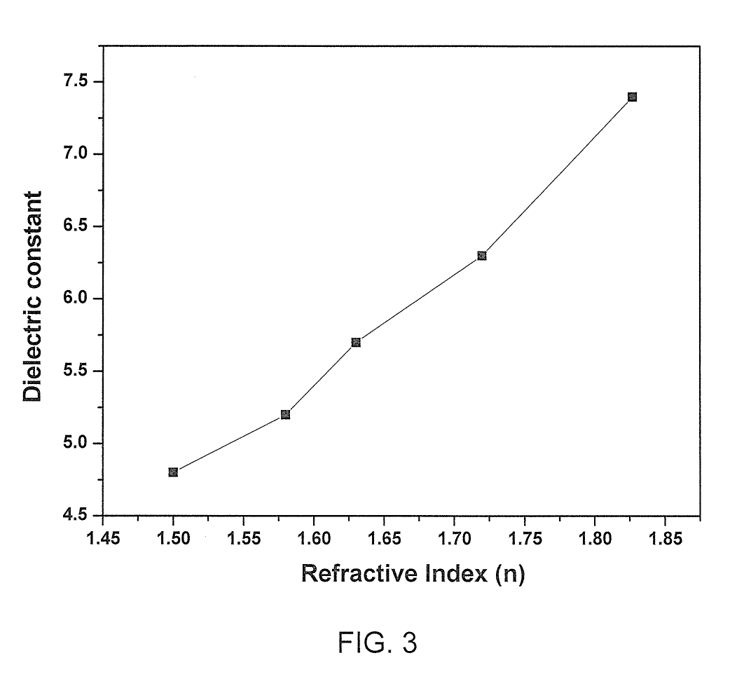

FIG. 3 illustrates a distribution curve of the electrical properties versus the optical properties of the dielectric layer formed according to an example of the present invention.

In the experiments shown in FIG. 3, the electrical analysis is performed to the dielectric layers with various refractive indexes. As illustrated by the curve shown in FIG. 3, as the refractive index of the dielectric layer increases from 1.49 to 1.83, the dielectric constant of the dielectric layer increases from 4.8 to 7.4. Since the dielectric constant of the dielectric layer increases with raising the refractive index thereof, the dielectric constant can also be controlled by the volumetric flow rate ratio and the process pressure.

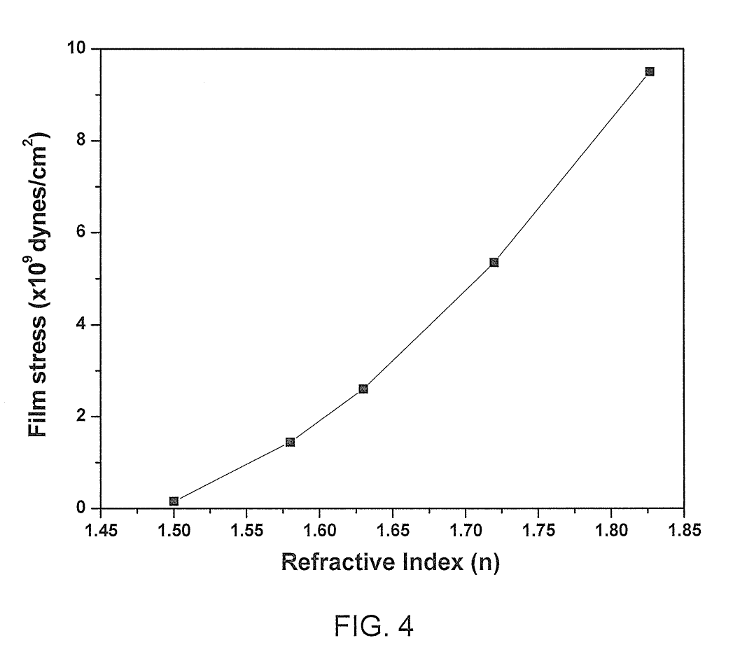

FIG. 4 illustrates a distribution curve of the physical characteristics versus the optical properties of the dielectric layer formed according to an example of the present invention.

In the experiments shown in FIG. 4, the physical characteristics of the dielectric layers with various refractive indexes are measured. In an example, film stress of the dielectric layer with a thickness of 1247 Å is measured as an indicator of the physical properties. As illustrated by the curve shown in FIG. 4, as the refractive index of the dielectric layer increases from 1.49 to 1.83, the film stress increases from 1.5×10⁸ dynes/cm² to 9.5×10⁹ dynes/cm². Accordingly, the film stress of the dielectric layer can also be controlled by the volumetric flow rate ratio and the process pressure, because the film stress increases with raising the refractive index thereof.

The methods described above are used for fabricating the dielectric layer with desired properties, and thus can be integrated into the applications of the current semiconductor process, such as MOS process or SONOS process. The method for fabricating the dielectric layer according to the present invention with the low thermal budget can be employed in the fabrication of tunnel oxide, trapping layers, top oxide of SONOS device, buffer layers and pad oxide, for example. In an example, when applying to the fabrication of high-k-used SONOS device, the dielectric layer formed according to the present invention can be substituted for each layer in the ONO structure by adjusting the process condition to obtain various dielectric layers with desired properties.

In the field of the non-volatile memory, several practical applications of the foregoing method for fabricating the dielectric layer according to this invention are provided below. It is to be understood that the following manufacturing procedures are intended to explain the fabrication of the silicon oxynitride layer in the non-volatile memory structure thereby enabling those of ordinary skill in the art to practice this invention, but are not intended to limit the scope of this invention. It is to be appreciated by those of ordinary skill in the art that other elements, such as the substrate, the gate structure and the doped regions, can be arranged and formed in a manner not shown in the illustrated embodiments according to known knowledges in the art.

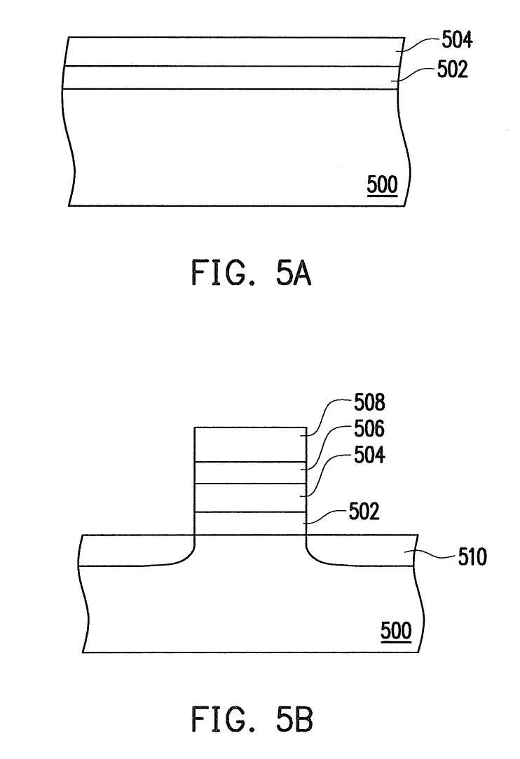

FIGS. 5A-5B are schematic cross-sectional views illustrating the fabrication process of a non-volatile memory according to a second embodiment of the present invention.

Referring to FIG. 5A, a substrate 500 is provided. The substrate 500 can be a semiconductor wafer, e.g. an N— or P-type silicon wafer. A tunnel layer 502 is then formed on the substrate 500. In an embodiment, the tunnel layer 502 can be a dielectric layer in the form of a single-layer structure. The material of the tunnel layer 502 is, for example, silicon oxide or other dielectric material with a high dielectric constant. The method of forming the tunnel layer 502 includes performing a chemical vapor deposition process, a rapid thermal process or a plasma oxidation process. The thickness of the tunnel layer 502 is about 10-100 Å, possibly 70 Å.

Thereafter, a charge-trapping layer 504 is formed on the tunnel layer 502. The charge-trapping layer 504 has a refractive index measured at a wavelength of 633 nm greater than or equal to 1.49, but less than 1.96. The material of the charge-trapping layer 504 is, for example, silicon oxynitride represented by the formula SiON or SiOₓN_{y}. It should be noted that the method of forming the charge-trapping layer 504 in the present embodiment includes introducing a reactant gas into a single-wafer LPCVD chamber, wherein the reactant gas includes SiH₄, N₂O and NH₃. The volumetric flow rate ratio of N₂O to (N₂O+NH₃) can be varied from 0.0245 to 0.375, while the volumetric flow rate of SiH₄ is constant, depending on the desired properties of the charge-trapping layer 504 to be formed. In an embodiment, the volumetric flow rate ratio of SiH₄ to (N₂O+NH₃) is within a range of 1:2000 to 6:2000, possibly 4:2000. In an exemplary example, SiH₄ is introduced into the single-wafer LPCVD chamber at a flow rate of about 4 sccm, N₂O is introduced thereinto at a flow rate of about 49-750 sccm, and NH₃ is introduced thereinto at a flow rate of about 1250-1951 sccm. Besides, an inert gas, such as argon (Ar) or helium (He), may be introduced into the single-wafer LPCVD chamber as a diluting gas or a carrier gas during the formation of the charge-trapping layer 504. A process pressure set in the formation of the charge-trapping layer 504 is within a range of 50 Torr to 200 Torr. A process temperature set in the formation of the charge-trapping layer 504 is within a range of 700° C. to 900° C., possibly 800° C. The charge-trapping layer 504 is, for example, formed on the tunnel layer 502 at a deposition rate of about 72-240 Å/minute. The duration of forming the charge-trapping layer 504 may be maintained in about 5-3600 seconds. The thickness of the charge-trapping layer 504 is about 30-100 Å, possibly 70 Å.

Next, referring to FIG. 5B, a top layer 506 is formed on the charge-trapping layer 504. The material of the top layer 506 may be silicon oxide, silicon oxynitride or other dielectric material having a high dielectric constant. The thickness of the top layer 506 is about 40-150 Å, possibly 90 Å. A gate 508 is then formed on the top layer 506. The gate 508 can be a metal layer or a metal silicide layer deployed on a polysilicon layer, for example. Thereafter, the gate 508, the top layer 506, the charge-trapping composite layer 504 and the tunnel layer 502 are defined and patterned so as to form a stacked structure. After the patterning process, a doped region 510 is formed in the exposed substrate 500 at both sides of the stacked structure as a source region or a drain region, so as to complete the process of manufacturing the non-volatile memory according to an embodiment of the present invention.

It is noted that the formation of the charge-trapping layer 504 in the method for fabricating the non-volatile memory according to the second embodiment of the present invention is carried out by single-wafer LPCVD. Further, the characteristics of the charge-trapping layer 504, e.g. refractive index, can be adjusted by varying the flow rate ratio of N₂O to NH₃. Thus, the process time and the thermal budget can be reduced effectively.

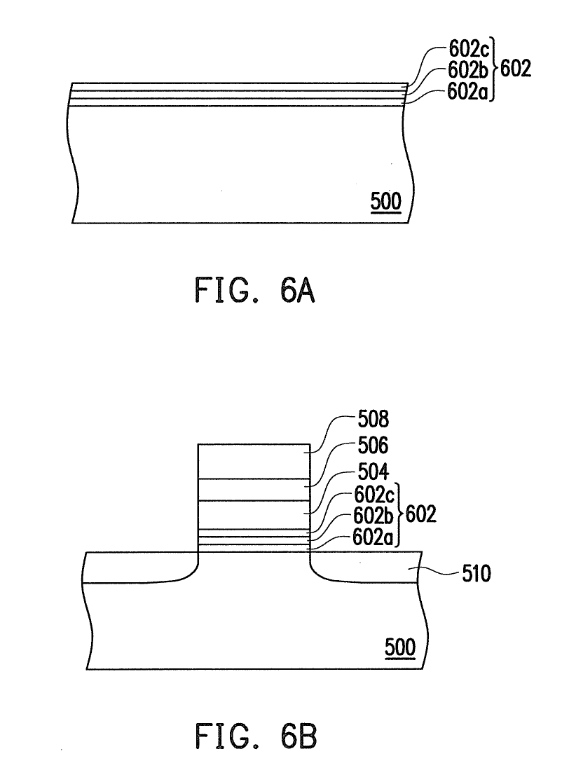

FIGS. 6A-6B are schematic cross-sectional views illustrating the fabrication process of a non-volatile memory according to a third embodiment of the present invention. It is noted that the manufacturing steps depicted in FIGS. 6A-6B are roughly identical to those depicted in FIGS. 5A-5B, while the difference lies in the formation of the tunnel layer. The identical elements shown in FIGS. 6A-6B and in FIGS. 5A-5B are designated with the same reference numbers, and the detailed descriptions of the same or like elements are omitted hereinafter.

Referring to FIG. 6A, a tunnel layer 602 is formed on the substrate 500. In another embodiment, the tunnel layer 602 formed on the substrate 500 can be in the form of a multi-layered structure. In other words, the tunnel layer 602 in the present embodiment includes a first oxide layer 602a, an oxynitride layer 602b and a second oxide layer 602c sequentially stacked on the substrate 500, wherein the oxynitride layer 602b has a refractive index below 1.63 measured at a wavelength of 633 nm so as to prevent charges from being trapped.

The method of forming the first oxide layer 602a includes forming a silicon oxide layer on the substrate 500 by performing a chemical vapor deposition process, atomic layer deposition process, a rapid thermal process or a plasma oxidation process, for example. The thickness of the first oxide layer 602a is about 8-15 Å, possibly 11 Å. The method of forming the oxynitride layer 602b includes forming a silicon oxynitride layer on the first oxide layer 602a using silane (SiH₄), nitrous oxide (N₂O) and ammonia (NH₃) as a reactant gas. The volumetric flow rate ratio of N₂O to (N₂O+NH₃) for forming the oxynitride layer 602b can be varied from 0.0245 to 0.375, while the volumetric flow rate of SiH₄ is constant, depending on the desired properties of the oxynitride layer 602b to be formed. In an embodiment, the volumetric flow rate ratio of SiH₄ to (N₂O+NH₃) for forming the oxynitride layer 602b is within a range of 1:2000 to 6:2000, possibly 4:2000. The formation of the oxynitride layer 602b is carried out in a single-wafer LPCVD chamber, for example. Also, an inert gas, such as argon (Ar) or helium (He), can be introduced into the single-wafer LPCVD chamber as a diluting gas or a carrier gas during the formation of the oxynitride layer 602b. A process pressure set in the formation of the oxynitride layer 602b is within a range of 50 Torr to 200 Torr. A process temperature set in the formation of the oxynitride layer 602b is within a range of 700° C. to 900° C., possibly 800° C. The oxynitride layer 602b is, for example, formed on the first oxide layer 602a at a deposition rate of about 72-240 Å/minute. The duration of forming the oxynitride layer 602b may be maintained in about 5-3600 seconds. The thickness of the oxynitride layer 602b is about 10-30 Å, possibly 20 Å. Thereafter, the method of forming the second oxide layer 602c includes forming a silicon oxide layer on the oxynitride layer 602b by performing a chemical vapor deposition process or atomic layer deposition process, for example. The thickness of the second oxide layer 602c is about 15-30 Å, possibly 25 Å.

Next, referring to FIG. 6B, a charge-trapping layer 504, a top layer 506 and gate 508 are formed on the tunnel layer 602 in sequence. Thereafter, the gate 508, the top layer 506, the charge-trapping composite layer 504 and the tunnel layer 602 are defined and patterned so as to form a stacked structure. A doped region 510 is then formed in the exposed substrate 500 at both sides of the stacked structure as a source region or a drain region, such that the method for fabricating the non-volatile memory according to another embodiment of the present invention is accomplished.

It is noted that the formation of the oxynitride layer 602b in the method for fabricating the non-volatile memory according to the third embodiment of the present invention is carried out in a similar manner of forming the charge-trapping layer 504 by tuning the characters of the film to be formed. Therefore, the time spent on the process and the thermal budget can also be reduced.

Furthermore, the actual measurement and analysis of the charge-trapping layer formed according to several examples of the present invention will be described, so as to substantiate the electrical properties of the charge-trapping layer in the non-volatile memory. It should be appreciated that this invention should not be construed as limited to the examples set forth herein.

### EXAMPLES II

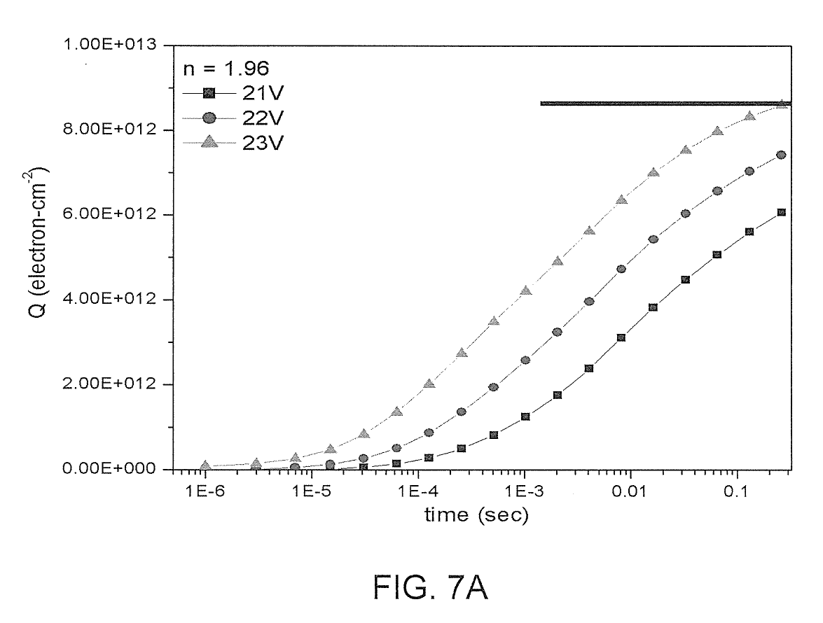

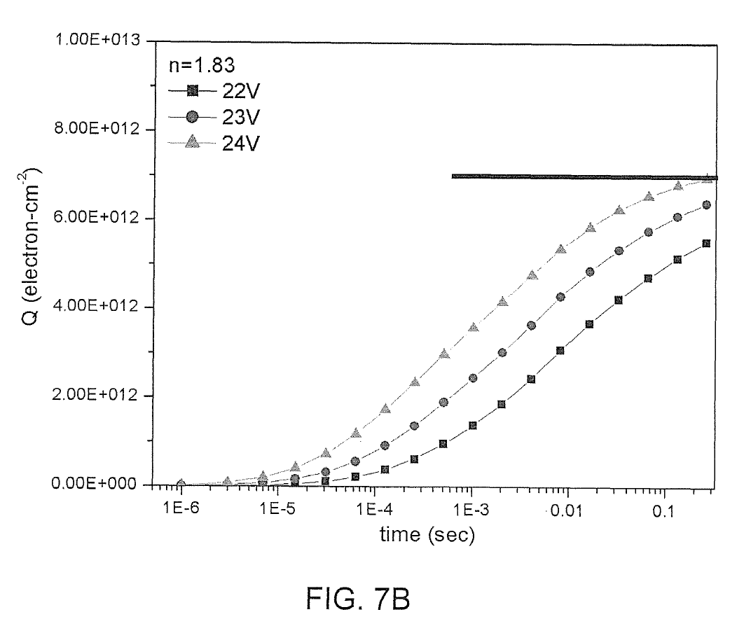

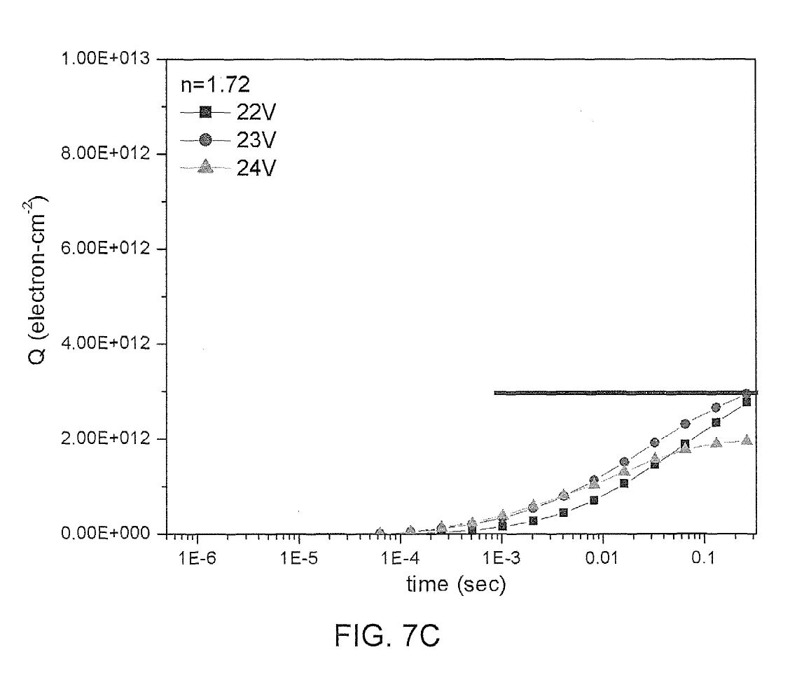

FIGS. 7A-7C respectively illustrate an effect of varied program time on electron density (Q) of the charge-trapping layer formed according to three examples of the present invention with different refractive indexes.

In the experiments shown in FIG. 7A, the charge-trapping layer has the refractive index of 1.96 (n=1.96) measured at a wavelength of 633 nm, and has a thickness of 70 Å. The charge-trapping layer is formed at the process pressure of 50 Torr and at the process temperature of 800° C. In this example, SiH₄ and NH₃ are fed into the chamber at the flow rate of 4 sccm and 2000 sccm respectively, while the reactant gas contains no N₂O.

In the experiments shown in FIG. 7B, the charge-trapping layer has the refractive index of 1.83 (n=1.83) measured at a wavelength of 633 nm, and has a thickness of 70 Å. The charge-trapping layer is formed at the process pressure of 50 Torr and at the process temperature of 800° C. In this example, SiH₄, N₂O and NH₃ are fed into the chamber at the flow rate of 4 sccm, 49 sccm and 1951 sccm, respectively.

In the experiments shown in FIG. 7C, the charge-trapping layer has the refractive index of 1.72 (n=1.72) measured at a wavelength of 633 nm, and has a thickness of 70 Å. The charge-trapping layer is formed at the process pressure of 200 Torr and at the process temperature of 800 ° C. In this example, SiH₄, N₂O and NH₃ are fed into the chamber at the flow rate of 4 sccm, 49 sccm and 1951 sccm, respectively.

As illustrated by the curves shown in FIGS. 7A, 7B and 7C, the electron density increases with the increase in the program time under various voltage. Comparing FIG. 7A with FIG. 7B, as the refractive index of the charge-trapping layer decreases from 1.96 to 1.83, the highest electron density decreases from about 9×10¹² electron/cm² to about 7×10¹² electron/cm². Comparing FIG. 7A with FIG. 7C, as the refractive index of the charge-trapping layer decreases from 1.96 to 1.72, the highest electron density decreases from about 9×10¹² electron/cm² to about 3×10¹² electron/cm². That is to say, the measured electron density representing the charge-trapping ability of the charge-trapping layer in the non-volatile memory is in direct proportion to the refractive index thereof.

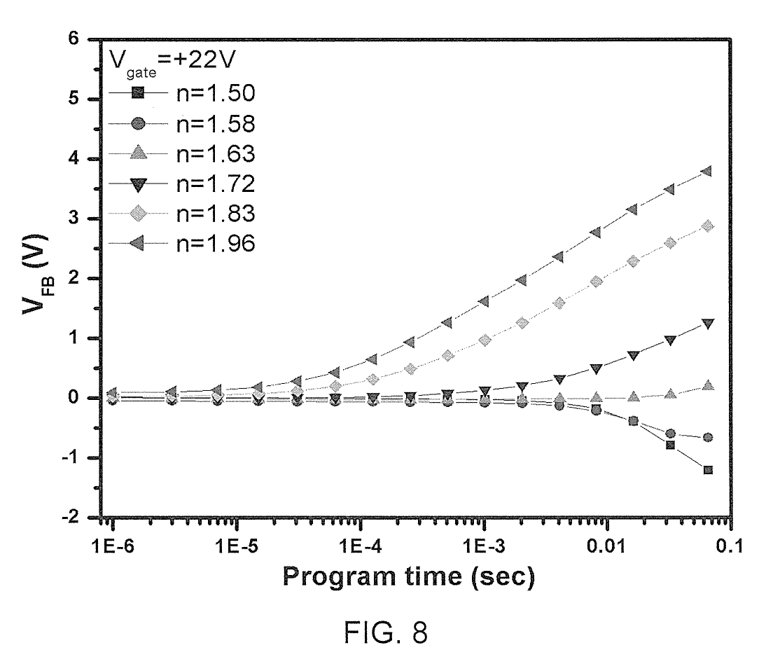

FIG. 8 illustrates distribution curves of flat band voltage (V_{FB}) versus varied program time of the non-volatile memory according to several examples of the present invention with different refractive indexes of the charge-trapping layer.

In the experiments shown in FIG. 8, each flat band voltage of the charge-trapping layers with various refractive indexes is measured at different program time under the gate voltage (V_{gate}) of +22V. As the refractive index of the charge-trapping layer decreases, the measured flat band voltage representing the program efficiency decreases. In other words, the charge-trapping efficiency of the charge-trapping layer is directly proportional to the refractive index thereof.

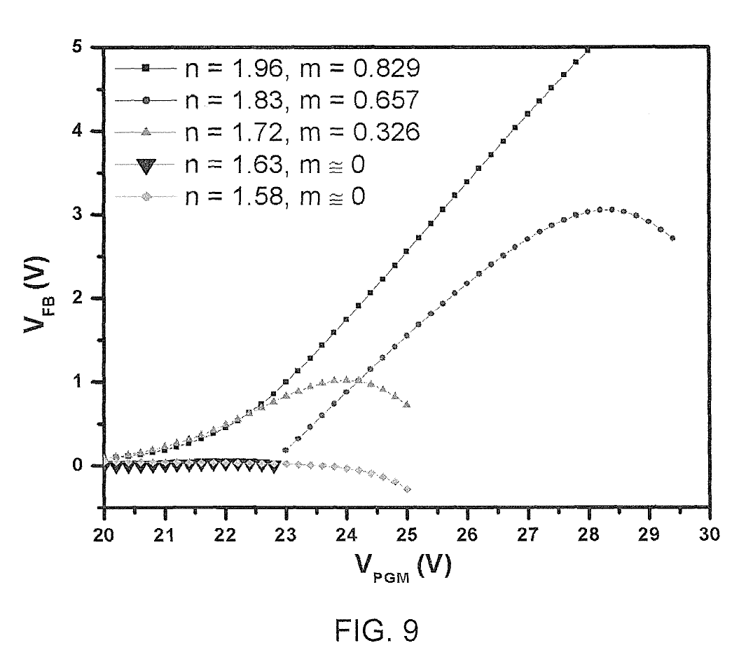

FIG. 9 illustrates distribution curves of flat band voltage (V_{FB}) versus varied program voltage (V_{PGM}) of the non-volatile memory according to several examples of the present invention with different refractive indexes of the charge-trapping layer.

In the experiments shown in FIG. 9, each flat band voltage of the charge-trapping layers with various refractive indexes is measured under a constant pulse program voltage in incremental-step-pulse programming (ISPP) scheme. The ISPP slope, designated as “m”, can be considered as the index of the charge capture capability. In general, the ideal ISPP slope for fully electron-capturing equals 1. The ISPP slope is independent of the starting voltage, pulse duration or voltage step. As illustrated by the curves shown in FIG. 9, the ISPP slope decreases from about 0.829 to 0 while the refractive index of the charge-trapping layer decreases from 1.96 to 1.58. Thus, the charge-trapping capability of the charge-trapping layer is diminished due to the reduction in the refractive index thereof.

In view of the above, the method for fabricating the dielectric layer in the present invention utilizes single-wafer LPCVD, and thus, thermal budget of the process can be reduced efficiently. Moreover, the properties of the dielectric layer to be formed can be adjusted by the flow rate ratio of the reactant gas and process pressure in the fabrication, so as to enable the dielectric layer to be applied to various devices as required.

Moreover, the method for fabricating the non-volatile memory in the present invention forms the charge-trapping layer and the tunnel barrier of the non-volatile memory by means of single-wafer LPCVD. The characteristics of the charge-trapping layer and the tunnel barrier can be adjusted by varying the flow rate ratio of the reactant gas. Hence, the process time and the thermal budget during the fabrication can be diminished.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for fabricating a dielectric layer comprising:
providing a substrate in a chamber, wherein the chamber is a single-wafer low-pressure chemical vapor deposition (LPCVD) chamber;
introducing a silicon source gas into the chamber;
introducing an oxidation source gas into the chamber;
introducing a nitridation source gas into the chamber; and
forming the dielectric layer with a dielectric constant within a range of 4.8 to 7.6 over the substrate.

2. The method according to claim 1, wherein the oxidation source gas to a total amount of the oxidation source gas and the nitridation source gas is varied within a range of 0.0245 to 0.375.

3. The method according to claim 1, wherein the oxidation source gas comprises nitrous oxide (N₂O).

4. The method according to claim 1, wherein the nitridation source gas comprises ammonia (NH₃).

5. The method according to claim 1, wherein the silicon source gas comprises silane (SiH₄).

6. The method according to claim 1, wherein a process pressure of the method is within a range of 50 Torr to 200 Torr.

7. The method according to claim 1, wherein a process temperature of the method is within a range of 700° C. to 900° C.

8. The method according to claim 1, wherein a refractive index of the dielectric layer is greater than or equal to 1.49 but less than 1.96 at a wavelength of 633 nm.

9. The method according to claim 1, wherein a film stress of the dielectric layer ranges between 1.5×10⁸ dynes/cm² and 1.35×10¹⁰ dynes/cm².

10. The method according to claim 1, wherein a duration of forming the dielectric layer on the substrate is within a range of 5 seconds to 3600 seconds.

11. A method for fabricating a dielectric layer, comprising:
providing a substrate in a deposition chamber;
setting a process pressure within a range of 50 Torr to 200 Torr;
introducing a reactant gas comprising silane (SiH₄), nitrous oxide (N₂O) and ammonia (NH₃) into the deposition chamber; and
forming a silicon oxynitride layer over the substrate.

12. The method according to claim 11, wherein a volume flow rate of SiH₄ is a constant.

13. The method according to claim 12, wherein a volume flow rate of N₂O to (N₂O+NH₃) is varied within a range of 0.0245 to 0.375

14. The method according to claim 10, wherein a volumetric flow rate ratio of SiH₄ to (N₂O+NH₃) is within a range of 1:2000 to 6:2000.

15. The method according to claim 10, wherein a process temperature of the method is within a range of 700° C. to 900° C.

16. The method according to claim 10, wherein a dielectric constant of the silicon oxynitride layer ranges between 4.8 and 7.6.

17. The method according to claim 10, wherein a refractive index of the silicon oxynitride layer is greater than or equal to 1.49 but less than 1.96 at a wavelength of 633 nm.

18. The method according to claim 10, wherein a film stress of the silicon oxynitride layer ranges between 1.5×10⁸ dynes/cm² and 1.35×10¹⁰ dynes/cm².

19. The method according to claim 10, wherein the deposition chamber is a single-wafer low-pressure chemical vapor deposition (LPCVD) chamber.

20. The method according to claim 10, wherein a duration of forming the silicon oxynitride layer on the substrate is within a range of 5 seconds to 3600 seconds.

21-37. (canceled)
